(19) United States
(12) Patent Application Publication
(10) Pub. No.: US 2012/0034369 A1
(43) Pub. Date: Feb. 9, 2012

(54) VAPORIZING APPARATUS, SUBSTRATE PROCESSING APPARATUS, COATING AND DEVELOPING APPARATUS, AND SUBSTRATE PROCESSING METHOD

(75) Inventors: Kazuhiko ITO, Koshi City (JP); Takahiro KITANO, Koshi City (JP); Tetsuo FUKUOKA, Koshi City (JP); Takayuki ISHII, Koshi City (JP)

(73) Assignee: TOKYO ELECTRON LIMITED, Tokyo (JP)

(21) Appl. No.: 13/197,875

(22) Filed: Aug. 4, 2011

(30) Foreign Application Priority Data
Aug. 5, 2010 (JP) 2010-176703

(51) Int. Cl. C23C 16/52; G03B 27/52; B05C 11/10

(52) U.S. Cl. 427/8; 118/712; 118/708; 355/27

(57) ABSTRACT

A vaporizing apparatus includes a heating plate disposed in a container to heat and vaporize a liquid chemical, a gas supply unit configured to supply a carrier gas carrying the chemical vaporized by the heating plate, into the container, a first detecting unit configured to detect the supply of the carrier gas into the container, and a second detecting unit configured to detect the vaporization of the liquid chemical by the heating plate.

### CROSS-REFERENCE TO RELATED APPLICATION

This application claims the benefit of Japanese Patent Application No. 2010-176703, filed on Aug. 5, 2010, in the Japan Patent Office, the disclosure of which is incorporated herein their entirety by reference.

### TECHNICAL FIELD

The present disclosure relates to a vaporizing apparatus for vaporizing a liquid chemical to generate a process gas for processing a substrate, such as a semiconductor wafer or a glass substrate for a flat panel display (FPD), a substrate processing apparatus including the vaporizing apparatus, a coating and developing apparatus including the substrate processing apparatus, and a substrate processing method.

### BACKGROUND

In a fabrication process for a semiconductor device or a FPD, a photolithography process is essentially necessary. In order to increase the adhesion between a wafer (or an underlayer) and a photoresist film formed in this process, a hydrophobization process is performed on the surface of the wafer before a photoresist liquid is applied onto the wafer. For example, the hydrophobization process is performed by spraying a hexamethyldisilazane (HMDS) gas (including vapor) onto the surface of the wafer. Because the hydrophobization process can prevent the photoresist film from peeling off, it is useful for a liquid-immersion exposing process that performs exposure by interposing water between a wafer and an exposure head.

A conventional substrate processing apparatus used in a hydrophobization process includes a storage tank for storing a HMDS liquid, a carrier gas supply source connected through a pipe to an inlet of the storage tank to supply a carrier gas into the storage tank, and a process chamber connected through a pipe to an outlet of the storage tank to receive a process target substrate (for example, Japanese Laid-open Patent Publication No. 10-41214). According to this apparatus, a carrier gas is supplied from the carrier gas supply source into the storage tank to bubble and vaporize a HMDS liquid in the storage tank, and the resulting HMDS gas is supplied into the process chamber together with the carrier gas. In the process chamber, the wafer is exposed to the HMDS gas, thereby hydrophobizing the surface of the wafer.

In the above substrate processing apparatus, the supply of the carrier gas into the storage tank is detected in order to detect that the wafer has been exposed to the HMDS gas (vapor). However, since the storage tank is spaced apart from the process chamber, a long pipe extending from the storage tank to the process chamber may cause some problems. For example, if a leakage occurs at the long pipe, there may be a case where it is determined that the wafer has not been exposed to the HMDS gas, even though the supply of the carrier gas is accurately detected. In another method, a manometer is installed at the pipe extended between the storage tank and the process chamber to detect the carrier gas containing the HMDS gas. However, it is difficult to detect, by the manometer, whether the HMDS gas is contained in the carrier gas.

However, in the above substrate processing apparatus, it is difficult to efficiently supply the HMDS gas because the supply amount of the HMDS gas is limited by the vapor pressure of the HMDS in the storage tank. In order to solve this problem, there has been proposed a vaporizing apparatus that directly vaporizes HMDS and carries the vaporized HMDS to the process chamber (for example, Japanese Laid-open Patent Publication No. 2009-194246). However, also in this apparatus, it is determined whether the wafer has been exposed to the HMDS gas, by detecting the supply of the carrier gas.

In the meantime, the HMDS gas may be detected in the process chamber in order to determine whether the wafer has been exposed to the HMDS gas. However, this requires a relatively massive HMDS detector, which causes the increase in the size of the substrate processing apparatus as well as the size of a coating and developing apparatus including the substrate processing apparatus, thus failing to satisfy a requirement for space saving. Also, the HMDS detector is expensive, thus increasing the cost of the substrate processing apparatus.

### SUMMARY

The present disclosure provides some embodiments of a vaporizing apparatus that can easily detect whether a process gas generated by vaporizing a chemical liquid is supplied to a substrate, a substrate processing apparatus including the vaporizing apparatus, a coating and developing apparatus including the substrate processing apparatus, and a substrate processing method.

According to a first embodiment of the present disclosure, a vaporizing apparatus includes: a heating plate disposed in a container to heat and vaporize a liquid chemical; a gas supply unit configured to supply into the container a carrier gas for carrying the chemical vaporized by the heating plate; a first detecting unit configured to detect the supply of the carrier gas into the container; and a second detecting unit configured to detect the vaporization of the liquid chemical by the heating plate.

According to a second embodiment of the present disclosure, a substrate processing apparatus includes: the vaporizing apparatus according to the first embodiment; a chamber configured to receive a susceptor on which a process target substrate is mounted; and an introducing unit configured to connect the vaporizing apparatus to the chamber and introduce a carrier gas containing a vaporized chemical from the vaporizing apparatus into the chamber.

According to a third embodiment of the present disclosure, a coating and developing apparatus includes: the substrate processing apparatus according to the second embodiment; a photoresist film forming unit configured to form a photoresist film on a substrate; and a developing unit configured to develop the photoresist film exposed after being formed by the photoresist film forming unit.

According to a fourth embodiment of the present disclosure, a substrate processing method includes: supplying a carrier gas into a container; performing a first detecting operation of detecting the supply of the carrier gas into the container; supplying a liquid chemical to a heating plate that is disposed in the container to heat and vaporize the liquid chemical; supplying the carrier gas carrying the vaporized chemical to a process target substrate; performing a second detecting operation of detecting the vaporization of the liquid chemical by the heating plate; and determining that the vaporized chemical has been supplied to the process target substrate, on the basis of the result of the first detecting operation and the result of the second detecting operation.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic side view of a vaporizing apparatus according to an embodiment of the present disclosure.

FIG. 2A is a schematic top view of a heating plate and a vaporizing plate used in the vaporizing apparatus of FIG. 1. FIG. 2B is a cross-sectional view of the heating plate and the vaporizing plate of FIG. 2A, taken along a line I-I.

FIG. 3 is a schematic side view of a substrate processing apparatus according to an embodiment of the present disclosure.

FIG. 4 is a view of a process gas supply unit of the substrate processing apparatus of FIG. 3.

FIG. 5 is a graph of an example of a temperature change accompanying the vaporization of a liquid chemical in the heating plate of the vaporizing apparatus of FIG. 1.

FIG. 6 is a top view of a coating and developing apparatus according to an embodiment of the present disclosure

FIG. 7 is a side view of the coating and developing apparatus of FIG. 6.

### DETAILED DESCRIPTION

Hereinafter, non-limitative exemplary embodiments of the present disclosure will be described in detail with reference to the accompanying drawings. Like reference numerals in the drawings denote like elements, and a duplicate description thereof will be omitted. Also, in the drawings, the sizes of elements and the relative sizes between elements are exaggerated for clarity of illustration. Therefore, the thicknesses and dimensions of elements should be determined in consideration of the non-limitative exemplary embodiments of the present disclosure by those skilled in the art.

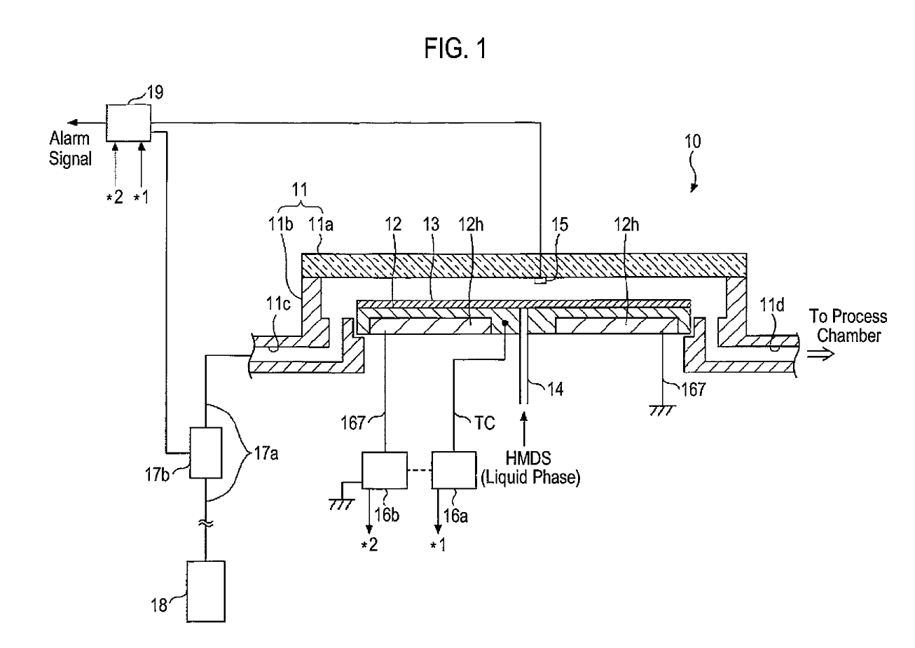

A vaporizing apparatus according to an embodiment of the present disclosure will be described below with reference to FIG. 1. Referring to FIG. 1, a vaporizing apparatus 10 according to an embodiment of the present disclosure includes a container 11, a heating plate 12 disposed in the container 11, and a vaporizing plate 13 mounted on the heating plate 12.

The container 11 includes a container body 11b and a ceiling plate 11a. For example, the container body 11b is formed of a stainless steel and has an approximately cylindrical shape, as shown in FIG. 1. An opening portion is formed at a bottom portion of the container 11, and the heating plate 12 is disposed to cover the opening portion. Specifically, the heating plate 12 is disposed at a bottom portion of the container body 11b, for example, by a metal seal (not shown). A supply pipe 11c and an exhaust pipe 11d are installed at the container body 11b. The supply pipe 11e is configured to guide a carrier gas from a carrier gas supply source 18 into the container 11. The exhaust pipe 11d is configured to introduce a carrier gas and an HMDS gas (including vapor), carried in the carrier gas, from the container 11 to a substrate processing apparatus (which will be described below). The supply pipe 11c and the exhaust pipe 11d are installed at the opposite sides of the bottom portion of the container body 11b with the heating plate 12 interposed therebetween.

The carrier gas supply source 18 and the supply pipe 11c are connected to each other by a carrier gas pipe 17a. For example, a valve (not shown) or a flow controller 17b such as a mass flow controller is installed at the carrier gas pipe 17a. Also, a nitrogen (N₂) gas may be used as the carrier gas. Also, an inert gas, such as helium (He), may be used as the carrier gas.

For example, the ceiling plate 11a is formed of an acrylic glass and is mounted on a top portion of the container body 11b, for example, through an O-ring (not shown). The O-ring is modified by the weight of the ceiling plate 11a to maintain a hermetic seal between the ceiling plate 11a and the container body 11b, thereby maintaining the airtightness of the container 11. Also, a sensor 15 (which will be described below) is installed at the ceiling plate 11a to face the heating plate 12. For example, the sensor 15 is connected to a conductive wire that is hermetically introduced into the container 11 through a current introduction terminal (not shown) installed at the ceiling plate 11a. Accordingly, a signal from the sensor 15 is inputted into a control unit 19.

The heating plate 12 is formed of a metal with a high thermal conductivity (e.g., aluminum) and has a disk shape in the present embodiment. For example, the heating plate 12 may have a diameter of about 50 mm to about 150 mm and may have a thickness of about 1 mm to about 10 mm (preferably about 4 mm). Also, a through hole is formed at an approximately central portion of the heating plate 12, and an HMDS supply pipe 14 is inserted thereinto. A HMDS supply source (not shown) is connected to the HMDS supply pipe 14, and a valve (not shown) or a flow controller is installed at the HMDS supply pipe 14 to control a flow of an HMDS liquid. According to this configuration, an HMDS liquid is supplied from the HMDS supply source to a top surface of the heating plate 12 at a flow rate controlled at a predetermined timing. Also, a heater 12h is embedded in the heating plate 12 to surround the HMDS supply pipe 14, and power is supplied to the heater 12h from a power supply unit 16b through a conductive wire 167. Accordingly, the heating plate 12 is heated. Also, a thermoelectric couple TC is embedded in the heating plate 12, a temperature of the heating plate 12 is measured and controlled by the thermoelectric, couple TC and a temperature controller 16a along with the power supply unit 16b. The heating plate 12 is heated to a temperature higher than an HMDS vaporization temperature, for example, to a temperature of about 50° C. to about 120° C. (preferably about 90° C.). Also, it is preferable that the thermoelectric couple TC has a front end (a temperature measurement end) spaced apart by a distance of about 2 mm from the top surface of the heating plate 12. If the front end of the thermoelectric couple TC is located at such a position, a temperature change of the heating plate 12 can be immediately detected.

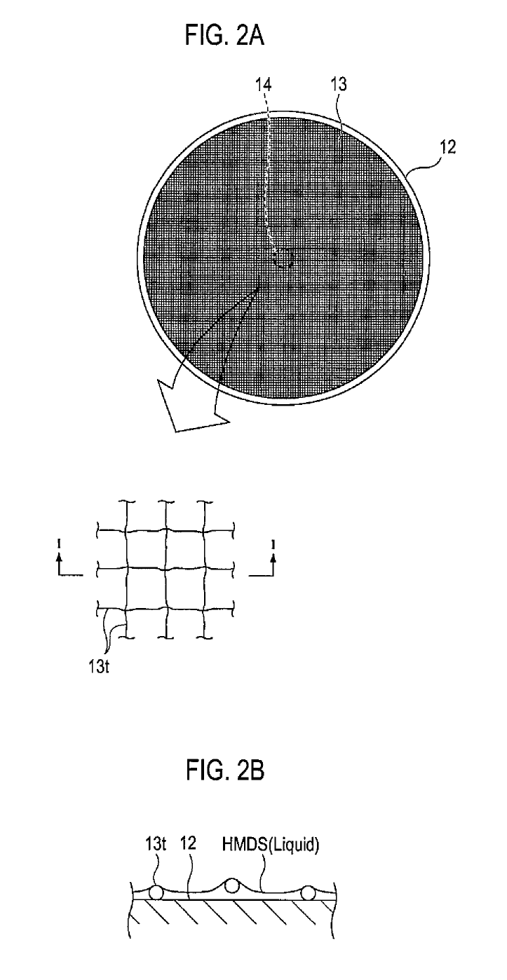

As shown in the upper portion of FIG. 2A, the vaporizing plate 13 mounted on the top surface of the heating plate 12 includes a mesh formed of a metal (e.g., a stainless steel), and has a diameter that is approximately equal to or slightly smaller than the diameter of the heating plate 12. As shown in the lower portion of FIG. 2A, the metal mesh may be formed of a metal wire 13t with a diameter of about 0.04 mm and may have a scale (a scale opening width) of about 0.05 mm to about 0.5 mm. When an HMDS liquid is supplied from the HMDS supply pipe 14 of FIG. 1 to the top surface of the heating plate 12, the HMDS liquid is thinly spread on the top surface of the heating plate 12 along the metal wire 13t of the vaporizing plate 13, as shown in FIG. 2B which is a cross-section view taken along a line I-I of FIG. 2A, and is efficiently vaporized by the heat generated from the heating plate 12. Also, the distance between the vaporizing plate 13 and the ceiling plate 11a may be, for example, about 0.5 mm to about 10 mm, preferably about 2 mm.

The control unit 19 is electrically connected to the sensor 15, the flow controller 17b, the temperature controller 16a, and the power supply unit 16b. Accordingly, the control unit 19 may receive an output signal from the sensor 15, a signal indicating the carrier gas flow rate from the flow controller 17b, a signal indicating the temperature of the heating plate 12 from the temperature controller 16a, and a signal indicating the power supplied from the power supply unit 16b to the heater 12h. Accordingly, for example, based on the signal indicating the carrier gas flow rate received from the flow controller 17b, and the signal indicating the temperature of the heating plate 12 received from the temperature controller 16a, the control unit 19 determines whether the HMDS gas vaporized and generated by the heating plate 12 has been supplied to a substrate processing apparatus (which will be described below) connected to the vaporizing apparatus 10. If it is determined that the HMDS gas vaporized and generated by the heating plate 12 has not been supplied to the substrate processing apparatus connected to the vaporizing apparatus 10, the control unit 19 may output an alarm signal. The alarm signal may be outputted to the substrate processing apparatus to stop an operation of the substrate processing apparatus. Alternatively or additionally, the alarm signal may be outputted to a warning lighting unit or a warning buzzer.

Also, the control unit 19 may not be electrically connected to all of the sensor 15, the flow controller 17b, the temperature controller 16a, and the power supply unit 16b. As described below, depending on which signal is to be used, the control unit 19 may be connected to any output source of the signal to be used.

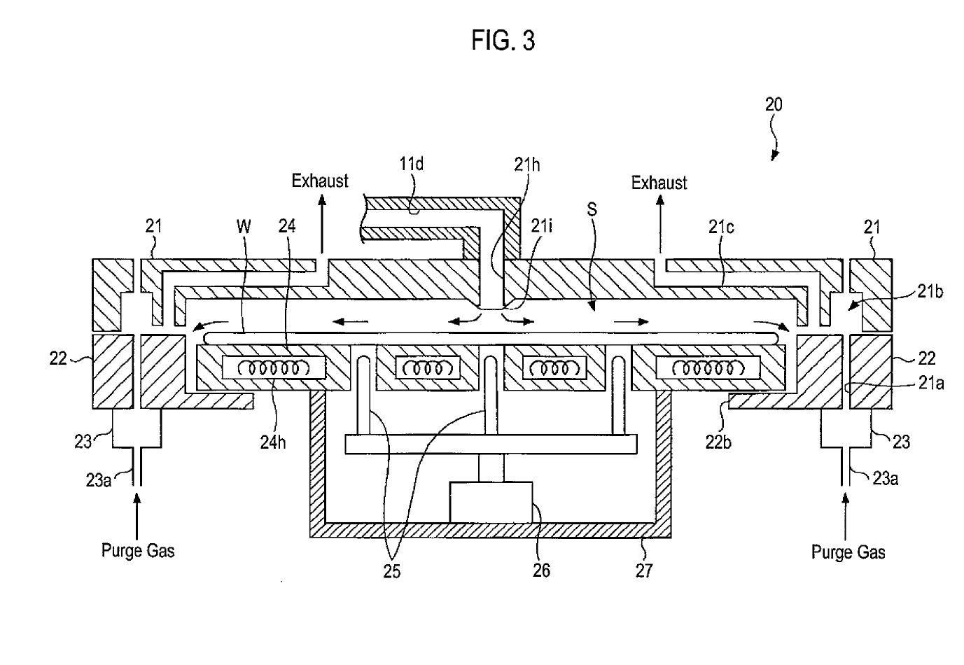

A substrate processing apparatus including a vaporizing apparatus according ₜo an embodiment of the present disclosure will be described below with reference to FIG. 3. As shown in FIG. 3, a substrate processing apparatus 20 according to an embodiment of the present disclosure includes a chamber body 22, a cover part 21 mounted on a top portion of the chamber body 22, and a susceptor 24 which is disposed in the chamber body 22 and on which a process target wafer is mounted.

The chamber body 22 is formed of, for example, a stainless steel and has a cylindrical shape with a flat bottom. An opening portion 22b is formed at a bottom portion of the chamber body 22, and the susceptor 24 is disposed to cover the opening portion 22b. The susceptor 24 is disposed at a bottom portion of the chamber body 22, for example, through a metal seal (not shown). An annular groove 23 is formed at a bottom surface of a sidewall portion of the chamber body 22. A plurality of purge gas supply pipes 23a are connected to a bottom portion of the annular groove 23, and a purge gas is supplied through the purge gas supply pipes 23a from a purge gas supply source (not shown). A plurality of through holes 22a is formed at the sidewall portion of the chamber body 22 to communicate with the annular grooves 23. The purge gas from the purge gas supply source may be supplied through the purge gas supply pipe 23a, the annular groove 23, and the through hole 22a to an internal space S that is defined by the chamber body 22 and the cover part 21. Also, a nitrogen (N₂) gas may be used as the purge gas, or an inert gas may be used as the purge gas.

Similar to the chamber body 22, the cover part 21 is formed of, for example, a stainless steel and has a cylindrical shape with a flat cover. The cover part 21 is mounted on a top portion of the chamber body 22, for example, through an O-ring (not shown), thereby maintaining the airtightness of the internal space S. Also, the cover part 21 and the chamber body 22 may be spaced apart from each other by a lift mechanism (not shown). When the cover part 21 and the chamber body 22 are spaced apart from each other, a carrier arm (not shown) is used to carry in the wafer onto the susceptor 24 and carry out the wafer from the susceptor 24.

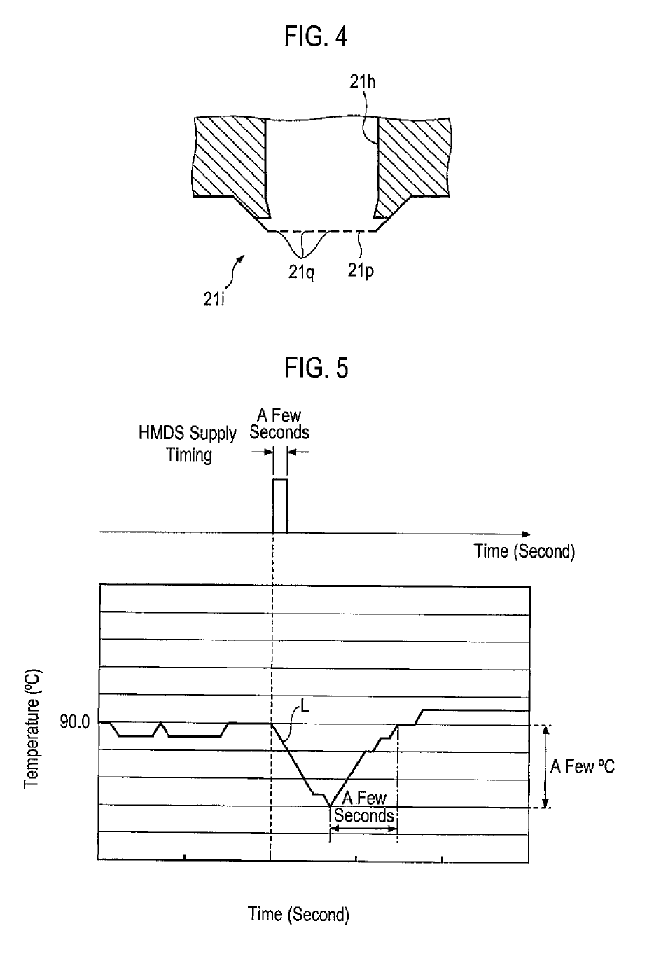

A through hole 21h is formed at an approximately central portion of the cover part 21 to communicate with the exhaust pipe 11d of the vaporizing apparatus 10. Specifically, the exhaust pipe 11d of the vaporizing apparatus 10 is hermetically coupled to a top surface of the cover part 21, for example, by a metal seal. Accordingly, a carrier gas from the vaporizing apparatus 10 and an HMDS gas carried by the carrier gas (hereinafter referred to as a carrier gas including an HMDS gas) are supplied to the internal space S of the substrate processing apparatus 20. Also, a supply terminal 21i is installed at a bottom portion of the through hole 21h. As illustrated in FIG. 4, the supply terminal 21i includes a plate 21p that is disposed at an opening of the through hole 21h and has a plurality of supply holes 21q formed therein. The respective supply holes 21q may have a diameter of, for example, about 0.5 mm to about 2 mm, and may be formed in a more dense distribution toward the outer periphery of the plate 21p. The carrier gas including the HMDS gas flows through the internal space S uniformly by the supply terminal 21i, and the wafer W mounted on the susceptor 24 is processed uniformly.

Referring back to FIG. 3, an annular groove 21b is formed in a sidewall portion of the cover part 21. The annular groove 21b communicates with the through hole 22a formed at a sidewall portion of the chamber body 22. An inner side of the annular groove 21b in the sidewall portion of the cover part 21 is spaced apart from the chamber body 22 by a predetermined distance. Through this space, the annular groove 21b communicates with the internal space S. Also, an exhaust pipe 21c is formed at the cover part 21. In an inside portion of the annular groove 21b, the exhaust pipe 21c is opened toward the chamber body 22 and to the top surface of the cover part 21. An opening of the exhaust pipe 21c on the top surface of the cover part 21 is connected to an exhaust device (not shown). Accordingly, the carrier gas including the HMDS gas supplied from the vaporizing apparatus 10 is exhausted into the internal space S of the chamber.

The susceptor 24 is formed of, for example, a metal and has a flat disk shape with a diameter greater than the diameter of the wafer W mounted on the susceptor 24. Also, it is preferable that three through holes are formed at the susceptor 24. Through these through holes, a lift pin 25 may be lifted by a lift mechanism 26. When the cover part 21 and the chamber body 22 are spaced apart from each other, the lift pin 25 and the carrier arm (not shown) cooperate to mount the wafer W on the susceptor 24 and lift the wafer W from the susceptor 24. Also, the lift pin 25 and the lift mechanism 26 is received in a housing 27 installed at a bottom surface of the susceptor 24, so that the lift pin 25 and the lift mechanism 26 are isolated from the external environment by the housing 27.

Also, a heater 24h is embedded in the susceptor 24, and the temperature of the susceptor 24 is controlled by a temperature sensor, a temperature controller and a heater power supply (not shown). Accordingly, the wafer W on the susceptor 24 is heated to a predetermined temperature and is exposed at the temperature to the HMDS gas received from the vaporizing apparatus 10, so that the surface of the wafer W is hydrophobized.

An operation of the vaporizing apparatus 10 and an operation of the substrate processing apparatus 20 (i.e., a substrate processing method) according to an embodiment of the present disclosure will be described below. In the following description, it is assumed that the signal indicating the carrier gas flow rate received from the flow controller 17b, and the signal indicating the temperature of the heating plate 12 received from the temperature controller 16a are inputted to the control unit 19 shown in FIG. 1.

### (Carrying-in Wafer to Substrate Processing Apparatus 20)

First, by the lift mechanism (not shown), the cover part 21 of the substrate processing apparatus 20 and the chamber body 22 (FIG. 3) are spaced apart from each other by a predetermined distance. Through the space between the cover part 21 and the chamber body 22, the carrier arm (not shown) is used to carry the wafer W onto the susceptor 24. Then, the lift pin 25 ascends and picks up the wafer W from the carrier arm. Then, the carrier arm is withdrawn, and the lift pin 25 descends and mounts the wafer W on the susceptor 24. Then, the cover part 21 and the chamber body 22 are brought into close contact with each other to maintain the airtightness of the internal space S.

### (Supplying Carrier Gas)

Thereafter, a carrier gas is supplied from the carrier gas supply source 18 of the vaporizing apparatus 10 through the carrier gas pipe 17a into the container 11 (refer to FIG. 1). The carrier gas supplied into the container 11 flows through the supply pipe 11c, the space of the container 11, the exhaust pipe 11d, the through hole 21h of the cover part 21 of the substrate processing apparatus 20, and the supply terminal 21i, into the internal space S of the substrate processing apparatus 20 (refer to FIG. 3). Then, the carrier gas is exhausted through the exhaust pipe 21c formed at the cover part 21 of the substrate processing apparatus 20. The internal space S of the substrate processing apparatus 20 is purged by this carrier gas flow. Also, during the purge of the internal space S, the purge gas is supplied through the purge gas supply pipe 23a, the annular groove 23, and the through hole 22a. The flow (i.e., exhaust flow) of the gas through the exhaust pipe 21c is controlled to be greater than the sum of the flow of the carrier gas supplied from the vaporizing apparatus 10 and the flow of the purge gas supplied from the purge gas supply pipe 23a. Accordingly, the internal space S maintains a negative pressure with respect to the external environment, which prevents the discharge of the HMDS gas into the atmosphere.

For example, when the carrier gas flows into the container 11 of the vaporizing apparatus 10, the flow controller 17b, outputs a carrier gas flow indication signal to the control unit 19. Based on the carrier gas flow indication signal which is inputted to the control unit 19, the control unit 19 determines that the carrier gas has been supplied into the container 11.

### (Supplying HMDS)

After the internal space S of the substrate processing apparatus 20 is purged, the heater 24h heats the susceptor 24 to heat the wafer W on the susceptor 24 to a predetermined temperature. After the temperature of the wafer W is stabilized at the predetermined temperature, the vaporizing apparatus 10 supplies an HMDS liquid from the HMDS supply source (not shown) through the HMDS supply pipe 14 to the heating plate 12 and the vaporizing plate 13. At this point, the heating plate 12 maintains a predetermined temperature (e.g., 90° C.). For example, the supply amount of the HMDS liquid (the supply amount of the HMDS liquid necessary to hydrophobize one wafer W) may be about 150 μl to about 200 μl. The supplied HMDS liquid is vaporized by the heating plate 12, and the vaporized HMDS gas is carried by the carrier gas to the internal space S of the substrate processing apparatus 20. Accordingly, the surface of the wafer Won the susceptor 24 is hydrophobized by being exposed to the HMDS gas.

FIG. 5 is a graph showing an example of a temperature change in the heating plate 12 when the HMDS liquid is supplied to the heating plate 12 and the vaporizing plate 13 of the vaporizing apparatus 10. In this example, the HMDS liquid is supplied to the substrate processing apparatus 20 for about 2 seconds. The HDMS liquid is vaporized by the heat from the heating plate 12 while spreading over the top surface of the heating plate 12 along the metal wire 13t (refer to FIG. 2) of the vaporizing plate 13. At this point, since the amount of heat released from the heating plate 12 corresponds to the vaporization heat, the temperature of the heating plate 12 decreases, for example, by a few degrees, as shown in FIG. 5. This temperature decrease is remarkable in comparison with the temperature stability of the heating plate 12 (e.g., about ±0.1° C. for a set value), and thus the generation of vaporization heat by the temperature decrease, that is, the supply of the HMDS liquid, can be detected. Specifically, when the temperature controller 16a outputs a signal indicating the temperature of the vaporizing plate 12 to the control unit 19, the control unit 19 determines that the HMDS liquid has been supplied to generate the HMDS gas, for example, based on the fact that the strength of the signal decreases below a predetermined threshold value.

As described above, the control unit 19 determines that the HMDS gas has been supplied to the substrate processing apparatus 20, by determining that the carrier gas has been supplied into the container 11 (hereinafter referred to as a first determination) and determining that the HMDS gas has been generated (hereinafter referred to as a second determination). On the other hand, if either the first determination or the second determination is not made even after the lapse of a predetermined time from the completion time point of the carry of the wafer W into the substrate processing apparatus 20, the control unit 19 determines that the HMDS gas has not been supplied to the substrate processing apparatus 20, and outputs an alarm signal to the substrate processing apparatus 20. In response to the alarm signal, the substrate processing apparatus 20 may stop the hydrophobization process and simultaneously output, for example, a signal for turning on a warning light or generating a warning sound. Accordingly, it is possible to prevent a photoresist film from being formed on the non-hydrophobized wafer W.

Also, as shown in FIG. 5, the temperature of the heating plate 12 is controlled by the temperature controller 16a and the power supply unit 16b to return to 90° C. within a few seconds after the temperature decrease. That is, the heating plate 12 can maintain a predetermined temperature until a hydrophobization process is performed on the next wafer W.

Modified embodiments of the vaporizing apparatus 10 will be described below. In the modified embodiments, different signals are used for determination by the control unit 19.

### First Modified Embodiment

In the first modified embodiment, the control unit 19 uses the output signal of the sensor 15 serving as a pressure sensor and the signal indicating the temperature of the heating plate 12 received from the temperature controller 16a. In this case, the control unit 19 may be electrically connected only to the sensor 15 and the temperature controller 16a.

Examples of the pressure sensor include a semiconductor diaphragm sensor, a capacitive sensor, an elastic diaphragm sensor, a piezoelectric sensor, a vibration sensor, a Bourdon tube sensor, and a bellows sensor. As shown in FIG. 1, since the sensor 15 as the temperature sensor is installed at the ceiling plate 11a in the container 11, it can detect the supply of the carrier gas from the pressure change in the container 11 when the carrier gas is supplied from the carrier gas supply source 18 through the carrier gas pipe 17a into the container 11. Specifically, if a signal indicating the pressure from the sensor 15 serving as a pressure sensor is inputted into the control unit 19, when the strength of the signal exceeds a predetermined threshold value, the control unit 19 determines that the carrier gas has been supplied (the first determination). Meanwhile, as described above, the generation of the HMDS gas is determined based on a signal indicating the temperature of the heating plate 12 received from the temperature controller 16a (the second determination). Accordingly, the control unit 19 determines that the HMDS gas has been supplied to the substrate processing apparatus 20. Meanwhile, if either the first determination or the second determination is not made within a predetermined time, the control unit 19 determines that the HMDS gas has not been supplied to the substrate processing apparatus 20, and outputs an alarm signal to the substrate processing apparatus 20.

### Second Modified Embodiment

In the second modified embodiment, the control unit 19 uses the output signal of the sensor 15 serving as a temperature sensor and the signal indicating the temperature of the heating plate 12 received from the temperature controller 16a. In this case, the control unit 19 may be electrically connected only to the sensor 15 and the temperature controller 16a.

Examples of the temperature sensor include a thermoelectric couple (TC) and a temperature measurement resistor such as a thermistor or a platinum resistance temperature detector. As shown in FIG. 1, since the sensor 15 is installed at the ceiling plate 11a in the container 11, it can detect the supply of the carrier gas from the temperature change in the container 11 when the carrier gas is supplied from the carrier gas supply source 18 through the carrier gas pipe 17a into the container 11. Specifically, since the heating plate 12 is heated to a temperature of about 90° C., the temperature in the container 11 is also approximately 90° C. in the normal state. However, if the carrier gas, whose temperature is maintained at about 23° C. equal to the environmental temperature in a crane room, is supplied into the container 11, the temperature in the container 11 is decreased by the carrier gas. Thus, if a signal indicating the temperature in the container 11 received from the sensor 15 serving as a temperature sensor is inputted into the control unit 19, when the strength of the signal exceeds a predetermined threshold value, the control unit 19 determines that the carrier gas has been supplied (the first determination). Meanwhile, as described above, the generation of the HMDS gas is determined based on a signal indicating the temperature of the heating plate 12 received from the temperature controller 16a (the second determination). Accordingly, the control unit 19 determines that the HMDS gas has been supplied to the substrate processing apparatus 20. Meanwhile, if either the first determination or the second determination is not made within a predetermined time, the control unit 19 determines that the HMDS gas has not been supplied to the substrate processing apparatus 20, and then outputs an alarm signal to the substrate processing apparatus 20.

### Third Modified Embodiment

In the third modified embodiment, instead of the thermoelectric couple TC, the power supply unit 16b supplying power to the heater 12h of the heating plate 12 of the vaporizing apparatus 10 is used as a detector unit for detecting the generation of the HMDS gas. In this case, the temperature controller 16a and the control unit 19 are not necessarily connected to each other. Instead, the power supply unit 16b is electrically connected to the control unit 19.

When a HMDS liquid is supplied to the heating plate 12 and the vaporizing plate 13 and the HMDS liquid is vaporized, the temperature of the heating plate 12 decreases, as described above. When this temperature decrease is detected by the thermoelectric couple TC, the power supply unit 16b increases the power supplied to the heater 12h, based on the signal received from the temperature controller 16a. Thus, if a signal indicating the power supplied from the power supply unit 16b to the heater 12h is inputted into the control unit 19, when the strength of the signal exceeds a predetermined threshold value, the control unit 19 determines that the HMDS gas has been generated (the second determination). Meanwhile, a signal received from one of the flow controller 17b, the pressure sensor 15, and the temperature sensor 15 is inputted into the control unit 19, and it is determined based on the signal that the carrier gas has been supplied (the first determination). Based on the first determination and the second determination, the control unit 19 determines that the HMDS gas has been supplied to the substrate processing apparatus 20. Meanwhile, if either the first determination or the second determination is not made within a predetermined time, the control unit 19 determines that the HMDS gas has not been supplied to the substrate processing apparatus 20, and then outputs an alarm signal to the substrate processing apparatus 20.

As described above, according to the vaporizing apparatus 10 according to the above embodiments (including the modified embodiments), the supply of the carrier gas is detected and a temperature decrease (corresponding to vaporization heat) of the heating plate 12 is detected during the vaporization of the HMDS liquid, thereby determining that the carrier gas containing the HMDS gas has been supplied to the substrate processing apparatus 20. Thus, a more reliable determination can be made as compared to the case where a determination is made only from the supply of the carrier gas. Also, since the vaporization heat of the HMDS liquid is detected, for example, from the temperature decrease of the heating plate 12 in a simplified manner, the supply of the HMDS gas can be determined more easily and cost-efficiently as compared to the case where an HMDS detecting sensor is installed in the internal space S of the substrate processing apparatus 20.

Also, for example, in the graph of FIG. 5, since the vaporization amount of the HMDS liquid can be estimated by an integral value of a line L which has an approximately V-shape (e.g., an area surrounded by the line L and a predetermined temperature (90° C.)), it is possible to quantify the HMDS gas exposed to the surface of the wafer W. Accordingly, it is possible to manage the reproducibility of the hydrophobization process in a stricter manner.

Also, since the heating plate 12 is formed of aluminum having a high thermal conductivity, the temperature decrease by the vaporization heat can be detected rapidly. Also, since the front end of the thermoelectric couple TC is disposed around the top surface of the heating plate 12 (e.g., about 2 mm from the top surface), the temperature decrease by the vaporization heat can be detected rapidly. Also, according to the substrate processing apparatus 20 including the vaporizing apparatus 10, since the supply of the HMDS gas from the vaporizing apparatus 10 is determined in a more simplified and cost-efficient manner, the wafer W in the substrate processing apparatus 20 can be surely exposed to the HMDS gas. That is, the advantages and effects of the vaporizing apparatus 10 are also provided in the substrate processing apparatus 20.

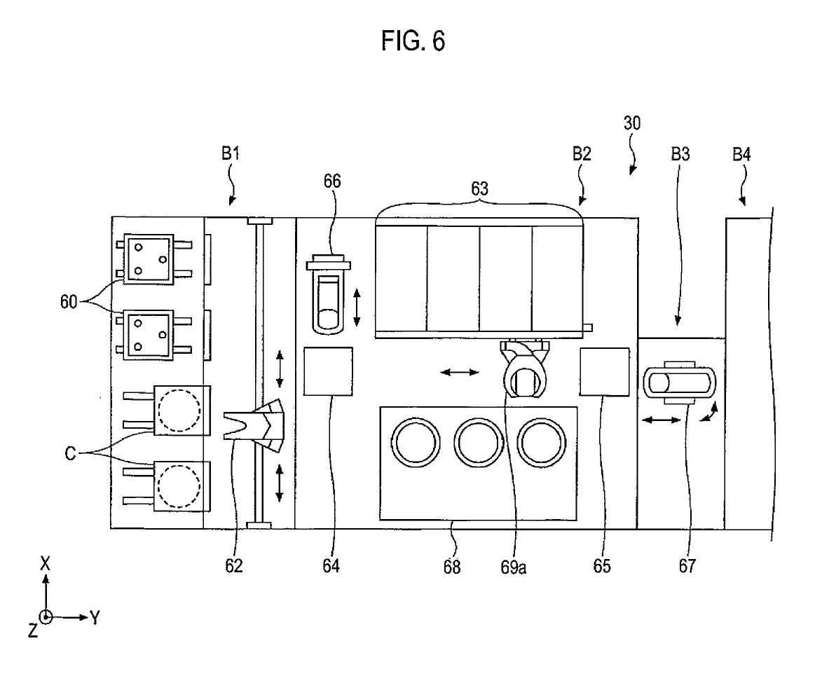

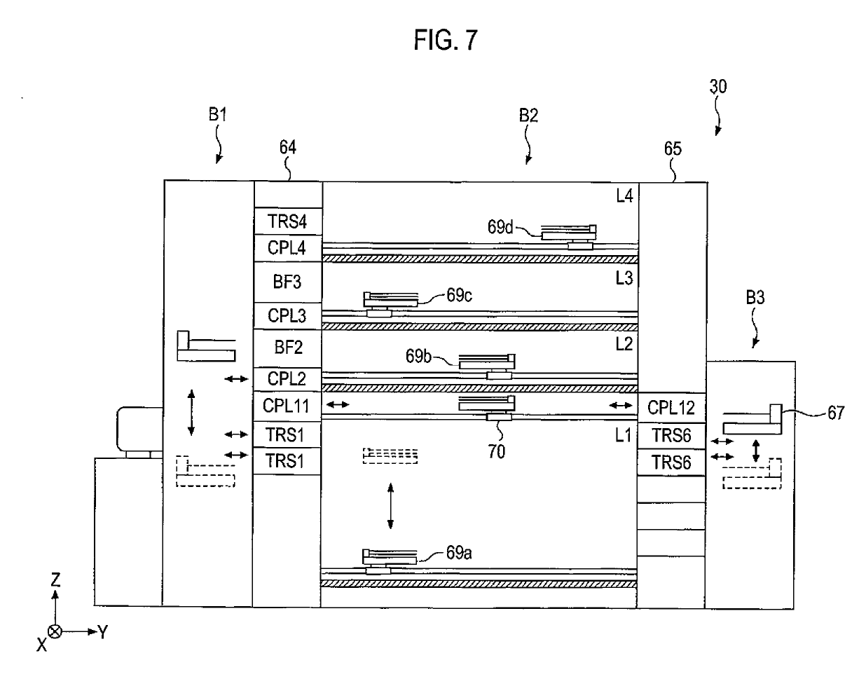

A coating and developing apparatus including a vaporizing apparatus and a substrate processing apparatus according to an embodiment of the present disclosure will be described below with reference to FIGS. 6 and 7. FIG. 6 is a top view of the coating and developing apparatus, and FIG. 7 is a side view of the coating and developing apparatus of FIG. 6. Referring to FIG. 6, a coating and developing apparatus 30 according to an embodiment of the present disclosure includes a carrier block B1, a process block B2, and an interface block B3. The interface block B3 is coupled to an exposing apparatus B4.

The carrier block B1 includes a mounting unit 60 on which a closed-type carrier C is mounted, and a carrier arm 62 for taking out a wafer from the carrier C mounted on the mounting unit 60, carrying the wafer to the process block B2, and receiving the wafer, processed by the process block B2, into the carrier C.

Referring to FIG. 7, in the process block B2, a DEV layer L1 for performing a developing process, a BCT layer L2 for forming an antireflection film as an underlayer of a photoresist film, a COT layer L3 for coating a photoresist liquid, and a TCT layer L4 for forming an antireflection film on the photoresist film, are installed sequentially from the bottom.

In the DEV layer L1, a developing unit 68 shown in FIG. 6 is stacked in a two-stage structure, and a carrier arm 69a is installed to carry the two-stage developing unit 68 to the wafer W. Although not shown in the drawings, a process unit group including a coating unit for spin-coating a chemical liquid to form an antireflection film, and a heating unit or a cooling unit for performing preprocessing and post-processing for the process performed in the coating unit, is installed in the BCT layer L2 and the TCT layer L4. Also, in order to transfer the wafer W between the respective units, a carrier arm 69b is installed in the BCT layer L2 and a carrier arm 69d is installed in the TCT layer L4. The vaporizing apparatus 10, the substrate processing apparatus 20, and a coating unit (not shown) for forming a photoresist film, are disposed in the COT layer L3.

Also, the above various units are stacked and disposed in a process unit group 63 of FIG. 6, corresponding to the respective layers L1 to L4. The vaporizing apparatus 10 and the substrate processing apparatus 20 according to an embodiment of the present disclosure are also disposed therein.

In the process block B2, a first shelf unit 64 is installed at the side of the carrier block B1, a second shelf unit 65 is installed at the side of the interface block B3, and a liftable carrier arm 66 is installed near the first shelf unit 64 to carry the wafer W between the respective units of the first shelf unit 64. A plurality of transfer units are installed in the first shelf unit 64 and the second shelf unit 65. Among the transfer units, the transfer units denoted by “CPL+numeral” are provided with a cooling unit for temperature control and the transfer units denoted by “BF+numeral” are provided with a buffer unit capable of mounting a plurality of wafers W.

The interface block B3 includes an interface arm 67 configured to transfer the wafer W between the second shelf unit 65 and the exposing apparatus B4. The exposing apparatus B4 performs an exposing process for the wafer W carried from the interface arm 67.

In this coating and developing apparatus 30, in a case of forming a photoresist pattern on the wafer W, the wafer W is carried by the carrier arm 62 from the carrier block B1 to the transfer unit of the first shelf unit 64, for example, the transfer unit CPL2 corresponding to the BCT layer L2. Then, the wafer W is carried by the carrier arm 66 to the transfer unit CPL3 and is carried by the carrier arm 69c into the COT layer L3. In the COT layer L3, the surface (or the uppermost layer) of the wafer W is hydrophobized by the vaporizing apparatus 10 and the substrate processing apparatus 20. Then, the wafer W is carried by the carrier arm 69c to the coating unit, in which a photoresist film is formed. Since the surface (or the uppermost layer) of the wafer W is hydrophobized, the photoresist film is formed to have a high adhesion with respect to the surface (or the uppermost layer) of the wafer W.

Thereafter, the wafer W is carried by the carrier arm 69c to the transfer unit BF3 of the first shelf unit 64. The wafer W carried to the transfer unit BF3 is carried by the carrier arm 66 to the transfer unit CPL4 and is carried by the carrier arm 69d to the TCT layer L4. Then, in the TCT layer L4, an antireflection film is formed on the photoresist film of the wafer W and it is carried to the transfer unit TRS4. Also, depending on requirements, an antireflection film is not formed on the photoresist film, or an antireflection film is formed directly on the wafer W in the BCT layer L2 instead of performing a hydrophobization process for the wafer W.

A shuttle arm 70 is installed at a top portion of the DEV layer L1 (refer to FIG. 7). The shuttle arm 70 is configured to directly carry the wafer W from the transfer unit CPL11 of the first shelf unit 64 to the transfer unit CPL12 of the second shelf unit 65. The wafer W having the photoresist film or the antireflection film is carried by the carrier arm 66 (FIG. 6) from the transfer unit BF3 or TRS4 to the transfer unit CPL11 and is carried by the shuttle arm 70 to the transfer unit CPL12.

The wafer W carried by the shuttle arm 70 to the transfer unit CPL12 is carried by the interface arm 67 (FIG. 6) of the interface block B3 to the exposing apparatus B4 through the interface block B3. Then, in the exposing apparatus B4, after the photoresist film formed on the wafer W exposed, the wafer W is carried by the interface arm 67 to the transfer unit TRS6 of the second shelf unit 65. Then, the wafer W is carried by the carrier arm 69a to the DEV layer L1. Herein, after the exposed photoresist film is developed, the wafer W is carried by the carrier arm 69a to the transfer unit TRS1 of the first shelf unit 64 and is received by the carrier arm 62 in the carrier C. In this manner, a photoresist pattern is formed on the wafer W by the coating and developing apparatus 30 according to an embodiment of the present disclosure.

The coating and developing apparatus 30 according to an embodiment of the present disclosure includes the vaporizing apparatus 10 and the substrate processing apparatus 20 according to an embodiment of the present disclosure, thereby making it possible to reliably perform a hydrophobization process using HMDS.

While certain embodiments have been described, these embodiments have been presented by way of example only, and are not intended to limit the scope of the disclosures. Indeed, the novel methods and apparatuses described herein may be embodied in a variety of substitutions and changes in the form of the embodiments described herein may be made without departing from the spirit of the disclosures.

The signal indicating the temperature of the heating plate 12 received from the temperature controller 16a may be, for example, an output voltage of the thermoelectric couple TC. That is, the temperature controller 16a receiving an output voltage from the thermoelectric couple TC may directly output the output voltage to the control unit 19. Also, instead of the thermoelectric couple TC, a temperature measurement resistor such as a thermistor or a platinum resistance temperature detector may be used to detect the temperature of the heating plate 12. Also, the signal indicating power supplied from the power supply unit 16b to the heater 12h may be, for example, a voltage of the power.

A mass flowmeter may be installed at the carrier gas pipe 17a of the vaporizing apparatus 10, the control unit 19 may be electrically connected to the mass flowmeter, and a signal indicating a flow rate from the mass flowmeter may be inputted into the control unit 19. Also, for example, a float-type flowmeter capable of outputting an electrical signal may be used instead of the mass flowmeter.

Also, the supply of the carrier gas may be detected by the thermoelectric couple TC installed at the heating plate 12 of the vaporizing apparatus 10. That is, when the supply of the carrier gas is initiated, since the temperature of the heating plate 12 is decreased by the carrier gas, the supply of the carrier gas may be detected by the temperature decrease. Also, since the temperature decreased by the supply of the carrier gas returns to a predetermined temperature during the supply of the HMDS liquid, the temperature decrease by the vaporization of the HMDS liquid may be detected by the thermoelectric couple TC. Thus, in this case, the supply of the carrier gas into the container 11 and the generation of the HMDS gas are detected by the thermoelectric couple TC. In other words, the thermoelectric couple TC may serve as both the detecting unit for detecting the supply of the carrier gas into the container 11 and the detecting unit for detecting the vaporization of the HMDS liquid by the heating plate 12.

It has been described that the heater 12h is embedded in the heating plate 12 of the vaporizing apparatus 10. However, instead of the heater 12h, a heating lamp such as an infrared lamp may be used to heat the heating plate 12.

In the coating and developing apparatus 30, the vaporizing apparatus 10 and the substrate processing apparatus 20 may be arranged, for example, horizontally or vertically. Also, the supply pipe 11c of the vaporizing apparatus 10 may be installed at the ceiling plate 11a, and the exhaust pipe 11d may be installed at the bottom portion of the container body 11b. In this case, the vaporizing apparatus 10 can be easily disposed on the substrate processing apparatus 20, thereby contributing to saving the space of the coating and developing apparatus 30.

In the above embodiment, the vaporizing apparatus 10 and the substrate processing apparatus 20 are disposed in the process unit group 63 of the coating and developing apparatus 30. However, the locations of the vaporizing apparatus 10 and the substrate processing apparatus 20 may be determined in consideration of the carrying efficiency of the wafer W. For example, the vaporizing apparatus 10 and the substrate processing apparatus 20 may be disposed to overlap with the developing unit 68, corresponding to the COT layer L3, together with the photoresist coating unit. Also, the vaporizing apparatus 10 and the substrate processing apparatus 20 may be disposed in the first shelf unit 64. The exhaust pipe 11d and the cover part 21 of the substrate processing apparatus 20 may be heated to a predetermined temperature in order to prevent condensing the HMDS gas vaporized by the heating plate 12 of the vaporizing apparatus 10. The HMDS chemical is provided as an example in the above description. However, the present disclosure is not limited thereto, and any other liquid chemicals may also be used. The vaporizing plate 13 is not limited to a metal mesh, and may be implemented using a mesh that has corrosion resistance against a liquid chemical, such as HMDS, and is formed of a material that does not erupt. Also, the HMDS liquid is not limited to being supplied from below by the HMDS supply pipe 14 piercing the heating plate 12, and may be dropped from above the heating plate 12 and the vaporizing plate 13.

In the above embodiments, the heating plate 12 and the vaporizing plate 13 have a circular top shape. However, the heating plate 12 and the vaporizing plate 13 may have a square or rectangular shape. In this case, the length of one side may be about 50 mm to about 150 mm.

In the above description, a semiconductor wafer is exemplified as the wafer W. However, the wafer W may be a glass substrate for a FPD. That is, the vaporizing apparatus, the substrate processing apparatus, the coating and developing apparatus, and the substrate processing method according to the embodiments of the present disclosure may be used not only to fabricate a semiconductor device but also to fabricate a FPD. Also, the wafer W may be a substrate having transistors, electrodes and interconnections formed through certain fabrication processes.

According to the embodiments of the present disclosure, it is possible to provide a vaporizing apparatus that can easily detect whether a process gas generated by vaporizing a liquid chemical has been supplied to a substrate, a substrate processing apparatus including the vaporizing apparatus, a coating and developing apparatus including the substrate processing apparatus, and a substrate processing method.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A vaporizing apparatus comprising:
a heating plate disposed in a container to heat and vaporize a liquid chemical;
a gas supply unit configured to supply into the container a carrier gas for carrying the chemical vaporized by the heating plate;
a first detecting unit configured to detect the supply of the carrier gas into the container; and
a second detecting unit configured to detect the vaporization of the liquid chemical by the heating plate.

2. The vaporizing apparatus of claim 1, wherein the second detecting unit comprises a first temperature sensor configured to detect a temperature of the heating plate.

3. The vaporizing apparatus of claim 2, wherein the first detecting unit is a flowmeter configured to detect a flow rate of the carrier gas.

4. The vaporizing apparatus of claim 2, wherein the first detecting unit is a pressure sensor configured to detect a pressure in the container.

5. The vaporizing apparatus of claim 2, wherein the first detecting unit is a temperature sensor configured to detect a temperature in the container.

6. The vaporizing apparatus of claim 2, further comprising a vaporizing plate made of a mesh disposed on the heating plate to spread the liquid chemical on the heating plate.

7. The vaporizing apparatus of claim 1, further comprising:
a heating element configured to heat the heating plate;
a second temperature sensor configured to detect a temperature of the heating plate heated by the heating element; and
a power supply unit configured to supply power to the heating element based on a signal from the second temperature sensor and operate as the second detecting unit based on a signal indicating the power supplied to the heating element.

8. The vaporizing apparatus of claim 7, wherein the first detecting unit is a flowmeter configured to detect a flow rate of the carrier gas.

9. The vaporizing apparatus of claim 7, wherein the first detecting unit is a pressure sensor configured to detect a pressure in the container.

10. The vaporizing apparatus of claim 7, wherein the first detecting unit is a temperature sensor configured to detect a temperature in the container.

11. The vaporizing apparatus of claim 7, further comprising a vaporizing plate made of a mesh disposed on the heating plate to spread the liquid chemical on the heating plate.

12. The vaporizing apparatus of claim 1, wherein the first detecting unit is a flowmeter configured to detect a flow rate of the carrier gas.

13. The vaporizing apparatus of claim 12, further comprising a vaporizing plate made of a mesh disposed on the heating plate to spread the liquid chemical on the heating plate.

14. The vaporizing apparatus of claim 1, wherein the first detecting unit is a pressure sensor configured to detect a pressure in the container.

15. The vaporizing apparatus of claim 14, further comprising a vaporizing plate made of a mesh disposed on the heating plate to spread the liquid chemical on the heating plate.

16. The vaporizing apparatus of claim 1, wherein the first detecting unit is a temperature sensor configured to detect a temperature in the container.

17. The vaporizing apparatus of claim 16, further comprising a vaporizing plate made of a mesh disposed on the heating plate to spread the liquid chemical on the heating plate.

18. The vaporizing apparatus of claim 1, further comprising a vaporizing plate made of a mesh disposed on the heating plate to spread the liquid chemical on the heating plate.

19. A substrate processing apparatus comprising:
a vaporizing apparatus including a heating plate disposed in a container to heat and vaporize a liquid chemical, a gas supply unit configured to supply into the container a carrier gas for carrying the chemical vaporized by the heating plate, a first detecting unit configured to detect the supply of the carrier gas into the container, and a second detecting unit configured to detect the vaporization of the liquid chemical by the heating plate;
a chamber configured to receive a susceptor on which a process target substrate is mounted; and
an introducing unit configured to connect the vaporizing apparatus and the chamber and introduce a carrier gas containing a vaporized chemical from the vaporizing apparatus into the chamber.

20. A coating and developing apparatus comprising:
a substrate processing apparatus;
a photoresist film forming unit configured to form a photoresist film on a substrate; and
a developing unit configured to develop the photoresist film exposed after being formed by the photoresist film forming unit,
wherein the substrate processing apparatus comprises:
a vaporizing apparatus including a heating plate disposed in a container to heat and vaporize a liquid chemical, a gas supply unit configured to supply into the container a carrier gas for carrying the chemical vaporized by the heating plate, a first detecting unit configured to detect the supply of the carrier gas into the container, and a second detecting unit configured to detect the vaporization of the liquid chemical by the heating plate;
a chamber configured to receive a susceptor on which a process target substrate is mounted; and
an introducing unit configured to connect the vaporizing apparatus and the chamber and introduce a carrier gas containing a vaporized chemical from the vaporizing apparatus into the chamber.

21. A substrate processing method comprising:
supplying a carrier gas into a container;
performing a first detecting operation of detecting the supply of the carrier gas into the container;
supplying a liquid chemical to a heating plate that is disposed in the container to heat and vaporize the liquid chemical;
supplying the carrier gas carrying the vaporized chemical to a process target substrate;
performing a second detecting operation of detecting the vaporization of the liquid chemical by the heating plate; and
determining that the vaporized chemical has been supplied to the process target substrate, based on the results of the first detecting operation and the second detecting operation.
